(19) United States
(12) Patent Application Publication
(10) Pub. No.: US 2006/0109061 A1
(43) Pub. Date: May 25, 2006

(54) System and method for narrow bandwidth amplitude modulation

(75) Inventors: Kevin G. Dobson, Reston, VA (US); James A. Bates JR., Leesburg, VA (US)

Correspondence Address: VENABLE LLP, P.O. BOX 34385, WASHINGTON, DC, 20045-9998, US

(73) Assignee: Masterwave, Inc., Reston, VA (US)

(21) Appl. No.: 11/274,279

(22) Filed: Nov. 16, 2005

Related U.S. Application Data
(60) Provisional application No. 60/629,583, filed on Nov. 22, 2004.

(51) Int. Cl. H03C 1/00

(52) U.S. Cl. 332/149

(57) ABSTRACT

A method and system for narrow band amplitude modulation in which audio is sampled periodically and held constant except during brief periods which are close to zero crossings of the carrier signal comprising an RF sine wave. The result is a modulated signal with sidebands of reduced amplitude. Without sidebands, the modulated RF sine wave may thus be very narrow banded, allowing many more stations to fit within the same band.

### BACKGROUND OF THE INVENTION

The present invention is directed to systems and methods of modulating a radio frequency (RF) sine wave with audio in such a way that audio changes (i.e., modulation) are applied to the RF sine wave only at the zero crossings of the RF sine wave. It should be understood that for the purposes used herein, the words “audio and video”, “audio”, and “baseband” may be used in various places throughout to refer to the modulating signal.

In order to accomplish this, the audio is sampled periodically and held constant except during brief periods which are substantially close to zero crossings of the RF sine wave. The result is a modulated signal with sidebands of substantially reduced amplitude. With sidebands of reduced amplitude, the modulated RF sine wave may thus be very narrow banded, allowing many more stations to fit within the same band.

With normal amplitude modulation techniques, an audio signal modifies an RF sine wave throughout the entire RF sine wave. This results in a modulated RF signal that is not a sine wave. Normal amplitude modulation techniques do not make an effort to limit the audio changes to the carrier zero crossings.

By using ordinary audio sampling techniques, and synchronizing the sample changes to the RF sine wave zero crossings, accurate sine waves of varying amplitude can be created. A perfect sine wave has no bandwidth. As a result, the modulation technique according to embodiments of the present invention maintains accurate RF sine waves and, thus; has sidebands of reduced amplitude.

The resulting sideband amplitude reduction depends on several factors, including how quickly the audio sample levels change, and how close the sample changes are to the RF sine wave zero crossing. If the audio changes can be made in practically no (i.e., approaching “zero”) time, the resulting modulated bandwidth may also be zero. As a result, and according to embodiments of the present invention, the audio can be changed in a relatively short time, that is on the order of about 20 nanoseconds (0.000000020 seconds) or less.

### BRIEF DESCRIPTION OF THE DRAWINGS

Preferred embodiments of the invention will now be described in connection with the associated drawings, in which:

FIG. 1 depicts amplitude modulation in the time domain;

FIG. 2 depicts a demodulation circuit;

FIG. 3 depicts amplitude modulation in the frequency domain;

FIGS. 4A and 4B depict sampling of a time-varying signal to produce a staircase waveform according to embodiments of the present invention;

FIG. 5 depicts an ideal narrowband amplitude modulation signal which may be produced according to the methods of certain embodiments of the present invention;

FIGS. 6A and 6B depict block diagrams of a system for narrow bandwidth amplitude modulation according to embodiments of the present invention;

FIG. 7 depicts a block diagram of a system for narrow bandwidth amplitude modulation according to an alternative embodiment of the present invention;

FIG. 8 depicts a functional block diagram of the digital signal processor (DSP) shown in FIG. 7;

FIG. 9 depicts an architectural diagram of the DSP shown in FIG. 8;

FIG. 10 depicts a typical basic system configuration with the DSP shown in FIGS. 8 and 9, two serial devices, a byte-wide EPROM, and optional external program and data overlay memories;

FIG. 11 depicts a functional block diagram of the direct digital synthesizer (DDS) shown in FIG. 7;

FIG. 12 depicts one example of the DDS shown in FIG. 7 in an amplitude modulation scheme;

FIG. 13 depicts a code fragment which, when used with the example shown in FIG. 12, may implement an amplitude modulation scheme with the DDS shown in FIG. 7;

FIGS. 14A and 14B depict a flow chart of a method according to embodiments of the present invention; and

FIGS. 15A and 15B depict before and after spectrum analyses of the simulated RF signal output from systems according to embodiments of the present invention.

### DETAILED DESCRIPTION OF PREFERRED EMBODIMENTS

In the following description and claims, the terms “connected” and “coupled,” along with their derivatives, may be used. It should be understood that these terms are not intended as synonyms for each other. Rather, in particular embodiments, “connected” may be used to indicate that two or more elements are in direct physical or electrical contact with each other. In contrast, “coupled” may mean that two or more elements are in direct physical or electrical contact with each other or that the two or more elements are not in direct contact but still cooperate or interact with each other.

An algorithm is here, and generally, considered to be a self-consistent sequence of acts or operations leading to a desired result. These include physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers or the like. It should be understood, however, that all of these and similar terms are to be associated with the appropriate physical quantities and are merely convenient labels applied to these quantities.

Unless specifically stated otherwise, as apparent from the following discussions, it is appreciated that throughout the specification discussions utilizing terms such as “processing,” “computing,” “calculating,” “determining,” or the like, refer to the action and/or processes of a computer or computing system, or similar electronic computing device, that manipulate and/or transform data represented as physical (e.g., electronic) quantities within the computing system's registers and/or memories into other data similarly represented as physical quantities within the computing system's memories, registers or other such information storage, transmission or display devices.

In a similar manner, the term “processor” may refer to any device or portion of a device that processes electronic data from registers and/or memory to transform that electronic data into other electronic data that may be stored in registers and/or memory. A “computing platform” may comprise one or more processors.

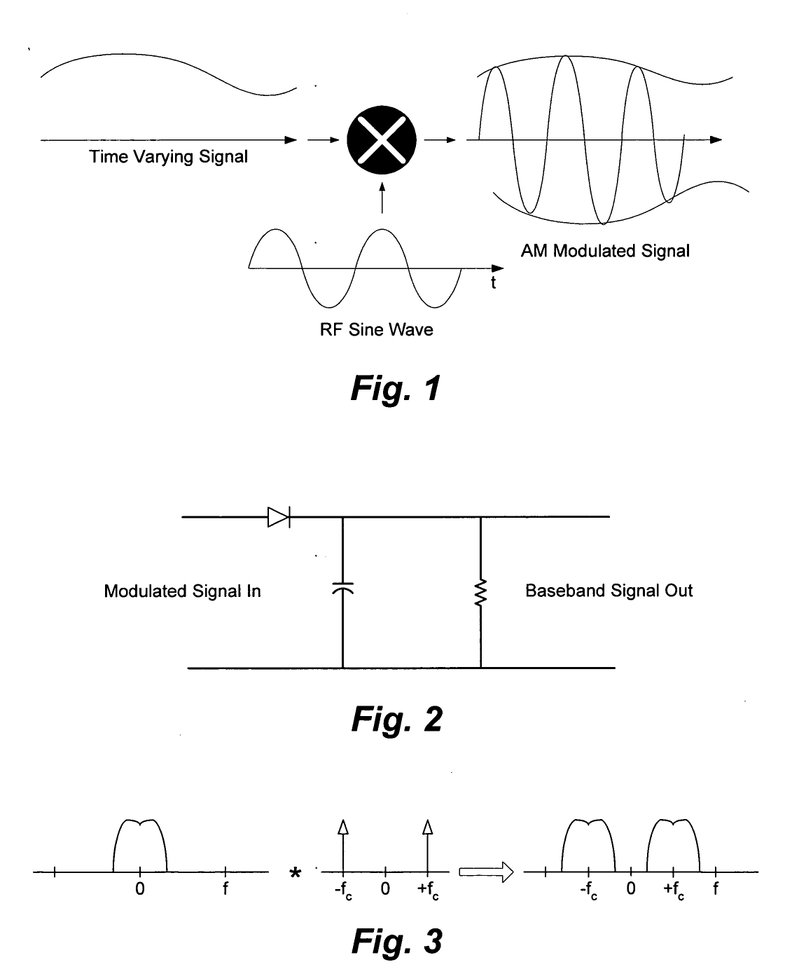

FIG. 1 depicts a system in which embodiments of the present invention may be implemented. Analog video and audio signals are time-varying signals with a finite bandwidth. For example, an amplitude modulated (i.e., AM) voice transmission could occupy a 6 kHz bandwidth, while a television transmission could occupy a 6 MHz bandwidth.

According to Fourier's Theorem, any time-varying signal can be represented as the sum of pure sinusoidal waveforms of different amplitudes. Thus, if one takes the highest and lowest frequency sinusoidal waves present in a time-varying signal and denote their frequencies as f2 and f1 respectively, then the bandwidth of the signal is f2−f1. The bandwidth of a pure sine wave, such as a carrier wave, is zero, as it is the sum of only one pure sinusoidal waveform where f2−f1=0.

To transmit time-varying (i.e., baseband) signals using AM, one would mix the time-varying signal with an RF carrier signal. The same process, as used herein, may be alternatively described as to mix, to multiply, or to modulate. This is graphically shown in FIG. 1.

On the receiving end, the original audio signal is recovered using an ordinary diode detector. See, e.g., FIG. 2.

As seen in FIG. 3, twice the bandwidth contained in the original baseband signal is required for transmission. This type of amplitude modulation is known as double side band amplitude modulation (DSB AM). From FIG. 3, one can readily appreciate that the spectrum is symmetrical about the carrier frequency. The carrier refers to the higher frequency RF input to a mixer.

Since the left and right halves of this spectrum contain the same information, either side can be suppressed before transmission to save bandwidth. The carrier is optional. This is known as single side band amplitude modulation (SSB AM).

SSB AM requires half the bandwidth as DSB AM. Further decreases in bandwidth can be achieved by processing the baseband signal. For example, the human voice is composed of frequency components, some of which can be eliminated without compromising intelligibility.

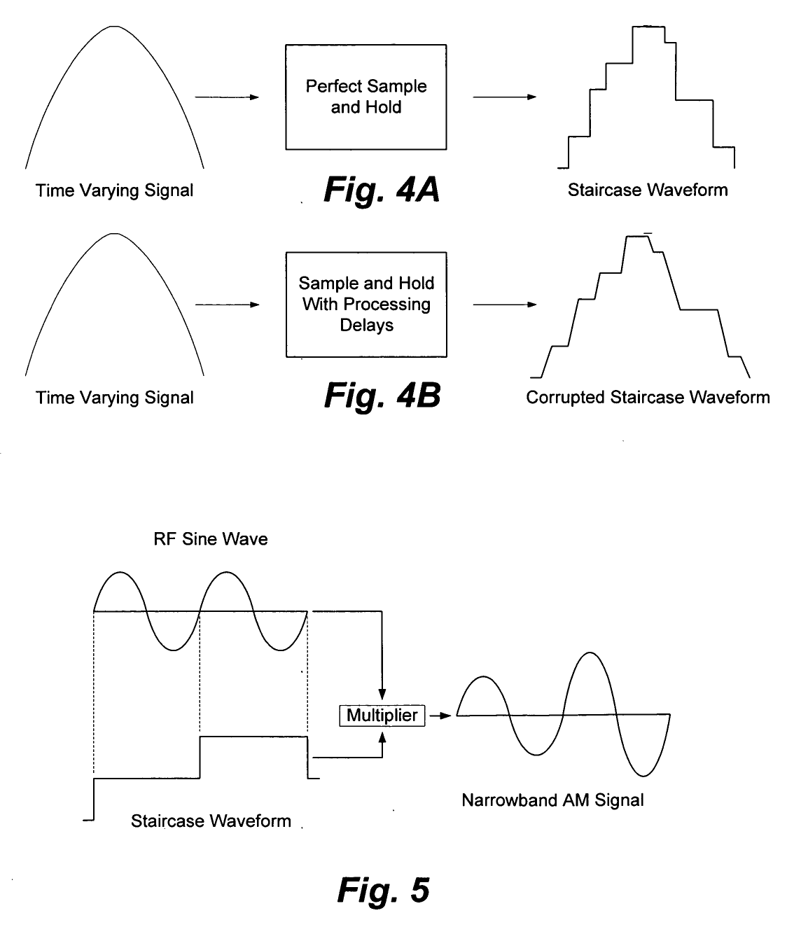

FIGS. 4A and 4B illustrate two sets of audio samples. The ideal signal, with square-wave like transitions is shown in FIG. 4A. The less than ideal signal with a slower transition is shown in FIG. 4B. Nyquist's Theorem states that for an analog signal to be converted to digital data, one must sample the analog signal at a rate that is at least twice its highest frequency component. Once this requirement is met, the sampled output can be used to reconstruct the original signal without any loss of information. A sampled analog signal results in a staircase waveform as shown in FIG. 4A.

A staircase waveform consists of periods of constant (i.e., horizontal) levels interspersed by rapid step-like (i.e., vertical) changes. A signal with a constant level has no frequency content, as it is not changing with time.

Step-like changes, on the other hand, are analogous to pulses in the time domain and a Fourier analysis will show that they have a broad frequency spectrum or large bandwidth. Multiplication of a carrier by a staircase function using normal amplitude modulation techniques, would yield: (a) a large bandwidth at the points where there are step-like changes; and (b) zero bandwidth during the periods of constant voltages.

The present invention discloses a form of modulation which reduces the bandwidth required for transmission to a theoretical minimum of 0 Hz. This is similar to traditional AM in that a carrier is multiplied by a baseband signal. However the baseband signal has been sampled resulting in the “ideal” staircase waveform previously described with respect to FIG. 4A.

In accordance with one important aspect of the present invention, the staircase waveform is applied to the carrier so that amplitude changes occur only at the exact time of a zero crossing of the unmodulated carrier. This eliminates the sidebands and results in a true “amplitude modulated” output signal with a theoretical zero bandwidth. This is illustrated in FIG. 5.

It may not be possible to achieve the ideal case, where there would be no sidebands. However, it would still be useful to have the sidebands at a greatly reduced amplitude. The multiplication of any number by another number approaching zero will result in a very small number nevertheless. That small result number which itself approaches zero represents the amplitude of the sidebands. An undesired effect, in the less than ideal case, is that the closer one gets to having a “vertical” transition of the modulating signal, the broader the low-level modulation will be. As a result, there will be very broad sidebands at low signal levels.

Building this form of modulator in the real world may result in less than ideal theoretical results, because of various limitations. First, the RF sine wave that will be modulated may be less than perfect, resulting in a wider bandwidth. Second, the sampled modulating signal (i.e., audio or video) will not have instantaneous level changes, nor will the signal stay at the “hold” level perfectly, because of the phenomenon known as sample-and-hold droop. Third, the RF sine wave zero crossing detection may not be exact. Fourth, the mixer stage may not be perfectly linear.

Since the shortest time period that the RF sine wave can contain a single modulating value is equal to one-half cycle of the RF sine wave, the chosen RF sine wave frequency will limit the number of samples (i.e., audio or video) that be applied to the RF sine wave. A 1 MHz RF sine wave (i.e., 1,000,000 cycles per second) would support one or two million modulating samples depending on the demodulation circuitry of the receiver. To support two million samples in this example, the detector diode in FIG. 2 must be replaced with a full wave rectifier.

There are many benefits of narrow band amplitude modulation according to the present invention. Narrow band amplitude modulation is less affected by some types of interference than is traditional AM. By receiving a narrower bandwidth, less interference is heard by the receiver. As is the case with traditional AM signals, detection of a narrow band amplitude modulation transmitted signal requires a peak detector, as shown in FIG. 2. Thus, new receiver designs are not required for the recovery of the original audio or video signal. Narrow band amplitude modulation can be used for both wireless and wire-line transmission.

As an alternative design (not shown), a fast DAC (i.e., digital to analog converter) may be used herein to directly generate the desired signals, without the use of a mixer chip. One example of this type of chip allows the generation of samples at 1.2 gigahertz (which means that the samples are created every 800 picoseconds). This means that the waveform created as a final output could be generated using this chip, to an accuracy of less than 1 nanosecond.

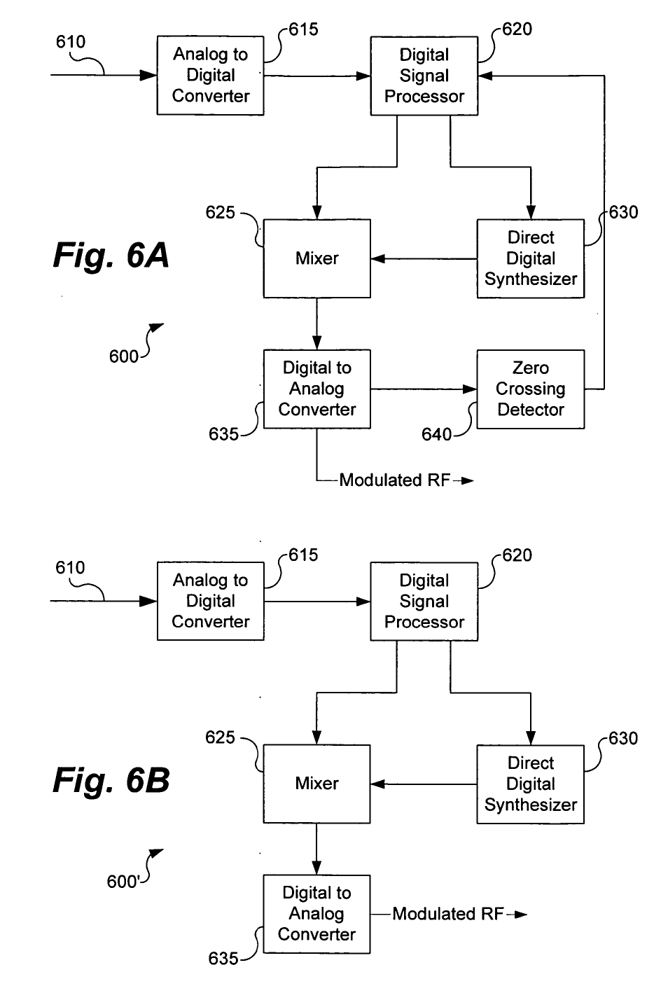

As a further alternative design, as shown in FIG. 6A, a system 600 according to another embodiment of the present invention may comprise a digital signal processor (DSP) 620, which is adapted to receive a digital audio signal from an analog to digital converter 615 coupled to a direct digital synthesizer (DDS) 630 and a mixer 625. A zero crossing detector 640 may be used in this embodiment to provide sync control to the DSP 620.

As a still further alternative design, a system 600′, as shown in FIG. 6B according to yet another embodiment of the present invention, includes no zero crossing detector. Moreover, DDS 630 as used in this embodiment may comprise a “DDS complete” device, since it includes the mixer 625, a modulator, and digital to analog converter 635.

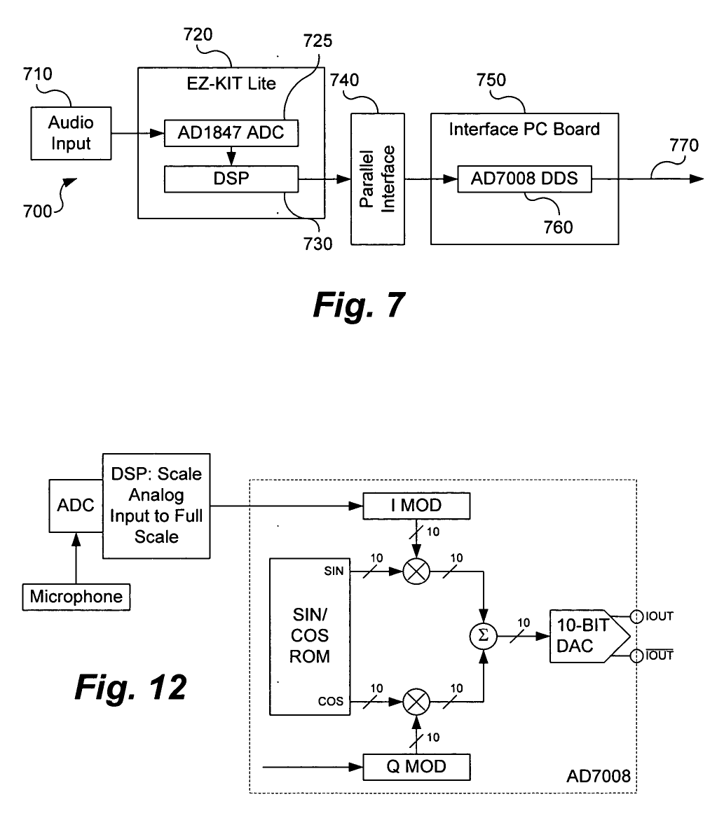

Referring now to FIG. 7, yet a further system 700 according to still another embodiment of the present invention will now be described. System 700 generally includes an audio input 710, which may be received by a DSP 730 through an analog-to-digital converter (ADC) 725. The DSP 730 may be any suitable DSP, but in this instance may be an AD2181 installed in an EZ-KIT Lite® (which is a registered trademark of Analog Devices, Inc. of Norwood, Mass. USA). Further details regarding the construction and operation of such DSP may be found in the ADSP-2181 EZ-KIT Lite® Evaluation System Manual (Revision 2.1, October 2003, Part Number 82-000543-01), the contents of which is incorporated by reference as if more fully set forth herein.

In this manner, audio input 710 may be coupled to ADC 725, such as an AD1847 SoundPort™ (a trademark of Analog Devices, Inc.) 16-bit stereo CODEC, which enables industry standard DSP multimedia architectures with a 70 dB dynamic range and −72 dB THD+N. ADC 725 also provides support for the 44-lead PLCC and TQFP package options; multiple channels of stereo input and output; analog and digital signal mixing; both digital interpolation and analog output low-pass on-chip signal filters; sample rates from 5.5 to 48 kHz; and a serial digital interface compatible with the entire ADSP-21XX/21XXX family of DSPs.

The output from ADC 725 may then be coupled through a parallel interface 740 to an interface PC board 750, which may include a DDS 760 such as the AD7008 CMOS DDS modulator from Analog Devices, Inc. The AD7008 direct digital synthesis chip 760 is essentially a numerically controlled oscillator employing a 32-bit phase accumulator, sine and cosine look-up tables and a 10-bit D/A converter integrated on a single CMOS chip. Modulation capabilities are provided for phase modulation, frequency modulation, and both in-phase and quadrature amplitude modulation suitable for QAM and SSB generation.

Clock rates up to 20 MHz and 50 MHz are supported by DDS 760. Frequency accuracy can be controlled to one part in 4 billion. Modulation may be effected by loading registers either through the parallel microprocessor interface or the serial interface. A frequency-select pin permits selection between two frequencies on a per cycle basis.

The serial and parallel interfaces may be operated independently and asynchronously from a DDS clock (not shown), wherein the transfer control signals may be internally synchronized to prevent metastability problems. The synchronizer can be bypassed to reduce the transfer latency in the event that the microprocessor clock is synchronous with the DDS clock. A power-down pin allows external control of a power-down mode (also accessible through the microprocessor interface). The AD7008 is available in 44-pin PLCC.

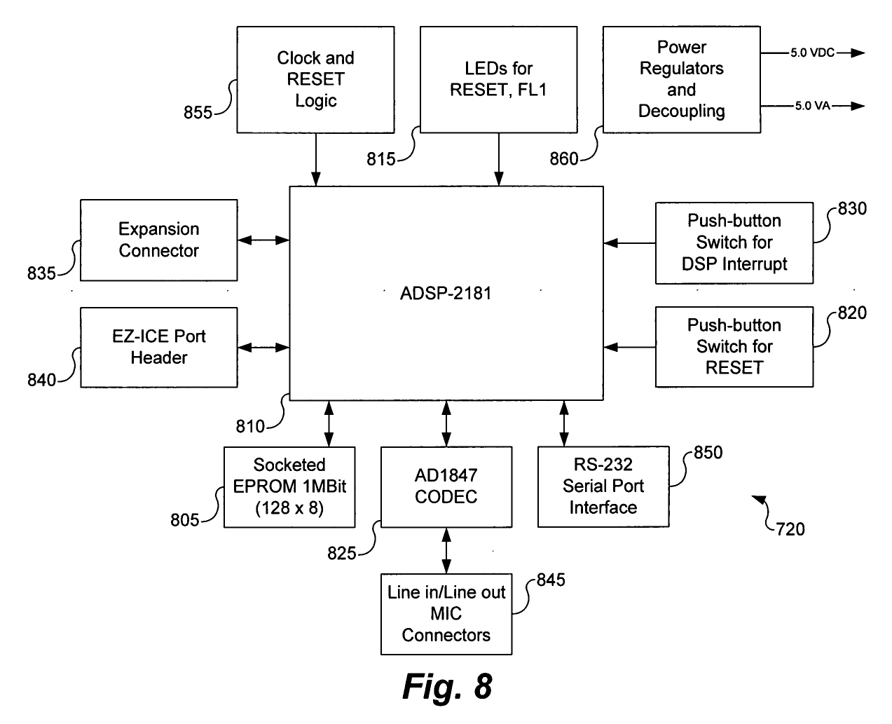

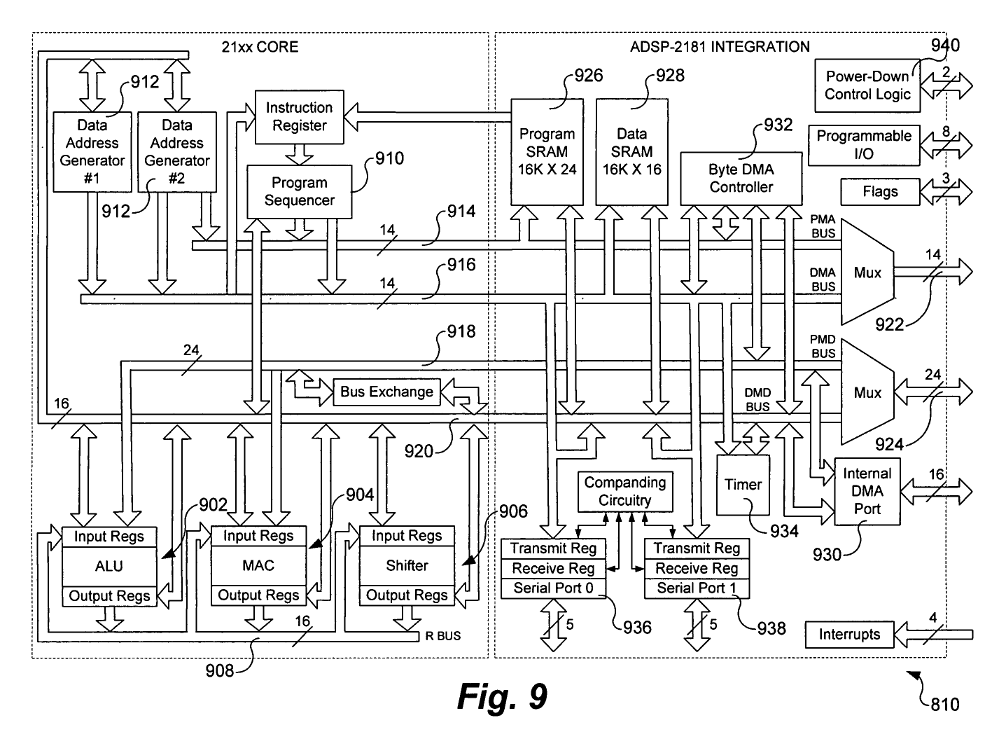

Referring now to FIGS. 8 and 9, further details regarding the operation of system 700 will now be described. FIG. 8 illustrates a detailed block diagram of the ADSP-2181 EZ-KIT Lite 720 shown in FIG. 7. Socketed EPROM 805 provides up to 128 k×8 bits of program storage that can be loaded by the ADSP-2181 processor or DSP 810 when it is programmed to boot from the socketed EPROM 805. After the DSP 810 is reset, a BDMA feature may be used to load the first 32 words of program memory from the byte memory space. Program execution may be held off until all 32 words are loaded.

Further details regarding program booting and processor modes may be found in the ADSP-218x DSP Hardware Reference (Revision 1.0, February 2001) and the ADSP-2181 DSP Microcomputer Data Sheet (Revision D, 1998), each of which is incorporated by reference as if more fully set forth herein. Programmers who are unfamiliar with Analog Devices 16-bit fixed-point processors may use both manuals in conjunction with the ADSP-218x DSP Instruction Set Reference (Revision 2.0, November 2004), which describe the processor architecture and instruction set and is also incorporated by reference as if more fully set forth herein.

The EZ-KIT Lite 720 also includes a pair of light emitting diodes (LEDs) 815. A D1 LED is a red light emitting diode, which is controlled by the FL1 output of DSP 810. Software may be used to control the state of this indicator by writing to an internal register. A D2 LED is a green light emitting diode, which is on whenever the board 720 has power.

The S1 switch is a reset push button switch 820. Pushing this button 820 causes DSP 810 and the AD1874 CODEC 825 to enter the hardware reset state and remain there until it is released. Outputs from switch 820 may be de-bounced electronically to prevent multiple transitions due to mechanical contact bounce. The S2 switch is an interrupt push button switch 830. Pushing this button 830 causes processor 810 to receive an IRQE interrupt input. DSP 810 then executes the current IRQE interrupt handler software if the interrupt is enabled and the IRQE interrupt vector is in place. Outputs from switch 830 may be de-bounced electronically to prevent multiple interrupts due to mechanical contact bounce.

The following describes the types of headers and connectors supplied with the EZ-KIT Lite 720. The J2 connector is also a ⅛-inch (3.5 mm) stereo jack. This jack is used to bring out line level audio signals from the board. The J3 connector is a female 9-pin D-Sub connector, which may be used to communicate with a host computer using RS-232 signal levels and asynchronous serial protocols. The J4 connector is a jack for a 5.5 mm cylindrical plug, which may be used to supply power to the board.

The JP1 jumper is a site for an 8-pin header, which may be used to configure the board 720 for EPROM sizes other than the 1 Mbit (128K byte) EPROM (27C010) shipped with the board 720. The JP2 jumper is a 6-pin header, which may be used to configure input jack J1 for either line level or microphone input. The center pin in each group of three is connected to one of the input pins of AD1874 CODEC 825. Jumpers (also known as shunts or shorting links) can be used to connect these pins to either the output of the microphone amplifier or to the output of the line level input filter. The P1 connector is a 14-pin header connector used to connect to an ADDS-218x EZ-ICE® in-circuit emulator.

The P2 and P3 connectors are sites for 50-pin header connectors. These connectors 835, 840 can be used to access the ADSP-2181 processor's signals for expansion or test purposes. The U2 socket is a socket for the EPROM 805 in a DIP package. As built, the board 720 accepts a 27C512 (64K byte) or 27C010 (128K byte) EPROM. Changing connections at JP1 allows the board to accept a 27C256 (32K byte), 27C020 (256K byte), 27C040 (512K byte), or 27C080 (1 Mbyte) EPROM. This socket is connected to the byte-wide memory interface of DSP 810.

The R28 resistor is a site for a zero-ohm resistor. If this resistor is installed processor 810 can reset the board 720 under software control. The software would assert reset by configuring the PF0 flag as an output and then setting it low. The R29 resistor is another site for a zero-ohm resistor. If this resistor is installed and X3 and C37 are removed, the CODEC 825 can operate off of the CLKOUT signal of processor 810 instead of its own 24.576 MHz clock. It may also be necessary to change X1 to a lower frequency value to stay within the CODEC's ratings.

The power connector, J4, supplies DC voltages to the EZ-KIT Lite board 720. When the AD1874 CODEC 825 is enabled on the EZ-KIT Lite board 720, the audio input and output jacks on the board may be accessed. Each of the audio connectors 845 is a stereo mini jack and accepts standard commercially available stereo mini plugs. The Microphone/Line_in Input jack connects to the LINE_IN_L (left) and LINE_IN_R (right) pins or the MIC1 and MIC2 of the AD1847 SoundPort stereo CODEC 825, depending on the setting of jumpers JP2. The LINE Output jack connects to the left (L) LINE_OUT and right (R) LINE_OUT pins of the CODEC 825.

When power is applied to the board, a reset circuit 850 holds the processor 810 in reset for approximately 30 ms. Reset is then de-asserted, and DSP 810 begins its boot process. The BMODE and MMAP pins on the processor 810 are grounded; DSP 810 boots from the byte-wide memory interface which is connected to the EPROM socket.

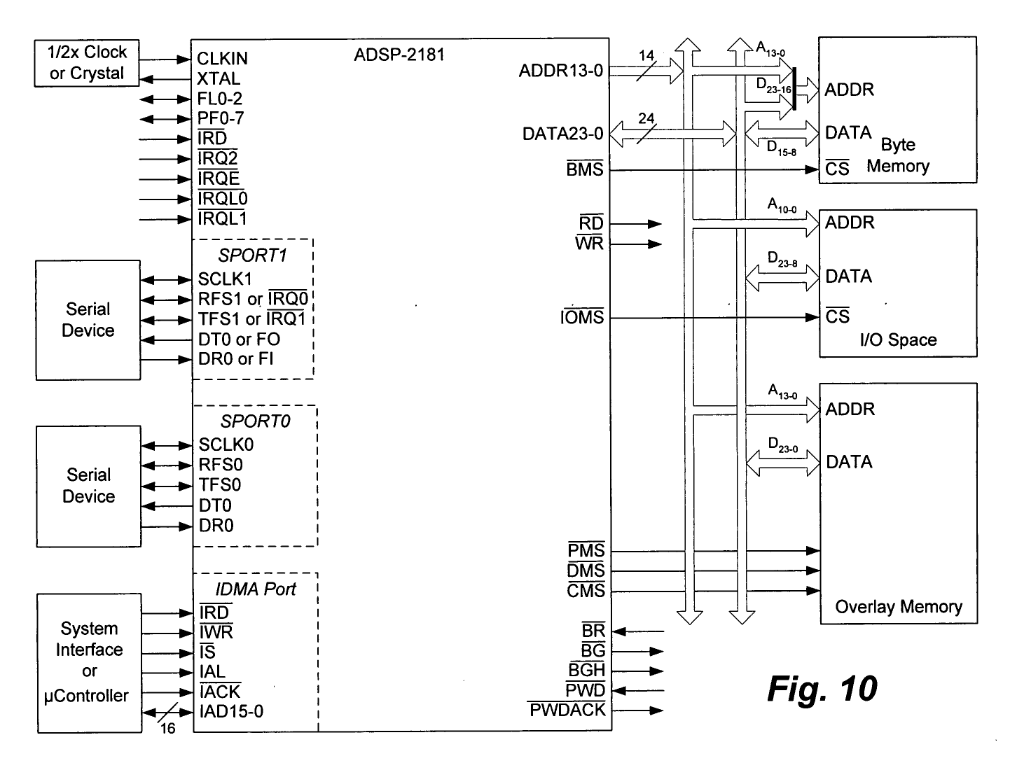

The EZ-KIT Lite board 720 is a mere example of the minimum implementation of an ADSP-2181 processor. Socketed EPROM 805 is connected to the DSP 810 via the Byte DMA Port. This interface uses only eight of the twenty-four data lines to carry data (D8 through D15) as shown in FIG. 10. Eight of the spare data lines (D16 through D23) are used to provide additional address bits. This allows the ADSP-2181 810 to address up to 32 Mbits (4 Mbytes) of memory. DSP 810 is configured to boot from the socketed EPROM 805 when RESET is de-asserted or if power is applied to the board.

The AD1874 CODEC 825 is connected to the DSP 810 via SPORT0. This high speed synchronous serial port carries all of the data, control, and status information between the DSP 810 and the CODEC 825. It is possible to disable the CODEC 825 if the serial port is to be used for another purpose. The CODECDIS signal available on connector P3 can be used to disable the CODEC 825. When this signal is brought low, the CODEC 825 is disabled and its signals are put in a high impedance state.

The SPORT1 pins are used to communicate with the host PC via the RS-232 interface (J3) 850. The Flag In and Flag Out pins carry the receive and transmit data. Software running on the DSP 810 emulates a UART to provide the proper protocol for asynchronous serial communications up to a data rate of 115K bits per second.

Architecture Overview

The ADSP-2181 instruction set provides flexible data moves and multifunction (i.e., one or two data moves with a computation) instructions. Every instruction can be executed in a single processor cycle. The ADSP-2181 assembly language uses an algebraic syntax for ease of coding and readability. A comprehensive set of development tools supports program development.

FIG. 9 is an overall block diagram of the ADSP-2181, which is shown generally in FIG. 8. The processor 810 contains three independent computational units: the ALU 902, the multiplier/accumulator (MAC) 904, and the shifter 906. The computational units process 16-bit data directly and have provisions to support multi-precision computations. The ALU 902 performs a standard set of arithmetic and logic operations; division primitives are also supported. The MAC 904 performs single-cycle multiply, multiply/add and multiply/subtract operations with 40 bits of accumulation. The shifter 906 performs logical and arithmetic shifts, normalization, de-normalization and derive exponent operations. The shifter 906 can be used to efficiently implement numeric format control including multiword and block floating point representations. An internal result (R) bus 908 connects the computational units 902, 904, 906 so that the output of any unit may be the input of any unit on the next cycle.

A powerful program sequencer 910 and two dedicated data address generators 912 ensure efficient delivery of operands to these computational units 902, 904, 906. The sequencer 910 supports conditional jumps, subroutine calls and returns in a single cycle. With internal loop counters and loop stacks, the ADSP-2181 executes looped code with zero overhead; no explicit jump instructions are required to maintain loops.

The two data address generators (DAGs) 912 provide addresses for simultaneous dual operand fetches (i.e., from data memory and program memory). Each DAG 912 maintains and updates four address pointers. Whenever the pointer is used to access data (e.g., by indirect addressing), it is post-modified by the value of one of four possible modify registers. A length value may be associated with each pointer to implement automatic modulo addressing for circular buffers.

Efficient data transfer is achieved with the use of five internal buses: (a) a program memory address (PMA) bus 914; (b) a program memory data (PMD) bus 916; (c) a data memory address (DMA) bus 918; (d) a data memory data (DMD) bus 920; and (e) the internal result (R) bus 908. The two address buses (PMA and DMA) 914, 918 share a single external address bus 922, allowing memory to be expanded off-chip, and the two data buses (PMD and DMD) 916, 920 share a single external data bus 924. Byte memory space and I/O memory space also share the external buses.

Program memory can store both instructions and data, permitting the ADSP-2181 to fetch two operands in a single cycle, one from program memory 926 and one from data memory 928. The ADSP-2181 can fetch an operand from program memory and the next instruction in the same cycle.

In addition to the address and data bus for external memory connection, the ADSP-2181 has a 16-bit Internal DMA port (IDMA port) 930 for connection to external systems. The IDMA port 930 is made up of 16 data/address pins and five control pins. The IDMA port 930 provides transparent, direct access to the DSP's on-chip program and data RAM 926, 928.

An interface to low cost byte-wide memory is provided by the Byte DMA port (BDMA port) 932. The BDMA port 932 is bi-directional and can directly address up to four megabytes of external RAM or ROM for off-chip storage of program overlays or data tables.

The byte memory and I/O memory space interface supports slow memories and I/O memory-mapped peripherals with programmable wait state generation. External devices can gain control of external buses with bus request/grant signals (\overline{BR}, \overline{BGH}, and \overline{BG}). One execution mode (Go Mode) allows the ADSP-2181 to continue running from on-chip memory. Normal execution mode requires the processor to halt while buses are granted.

The ADSP-2181 can respond to 13 possible interrupts, eleven of which are accessible at any given time. There can be up to six external interrupts (e.g., one edge-sensitive, two level-sensitive and three configurable) and seven internal interrupts generated by the timer 934, the serial ports (SPORTs) 936, 938 the Byte DMA port 932 and the power-down circuitry 940. There is also a master \overline{RESET} signal.

The two serial ports 936, 938 provide a complete synchronous serial interface with optional companding in hardware and a wide variety of framed or frameless data transmit and receive modes of operation. Each port 936, 938 can generate an internal programmable serial clock or accept an external serial clock.

The ADSP-2181 provides up to 13 general-purpose flag pins. The data input and output pins on SPORT938 can be alternatively configured as an input flag and an output flag. In addition, there are eight flags that are programmable as inputs or outputs and three flags that are always outputs.

A programmable interval timer 934 generates periodic interrupts. A 16-bit count register (TCOUNT) is decremented every n processor cycles, where n is a scaling value stored in an 8-bit register (TSCALE). When the value of the count register reaches zero, an interrupt is generated and the count register is reloaded from a 16-bit period register (TPERIOD).

As noted briefly above, the ADSP-2181 incorporates two complete synchronous serial ports (SPORT0 and SPORT1) 936, 938 for serial communications and multiprocessor communication. The following is a brief list of the capabilities of SPORTs 936, 938. Further details may be found in the ADSP-2100 Family User's Manual (Third Edition, September 1995), which is incorporated by reference as if more fully set forth herein.

SPORTs 936, 938 are bidirectional and have a separate, double buffered transmit and receive section. They can use an external serial clock or generate their own serial clock internally. SPORTs 936, 938 have independent framing for the receive and transmit sections. Sections run in a frameless mode or with frame synchronization signals internally or externally generated. Frame sync signals are active high or inverted, with either of two pulsewidths and timings.

SPORTs 936, 938 support serial data word lengths from 3 to 16 bits and provide optional A-law and μ-law companding according to CCITT recommendation G.711. Their receive and transmit sections can generate unique interrupts on completing a data word transfer. SPORTs 936, 938 can receive and transmit an entire circular buffer of data with only one overhead cycle per data word. An interrupt is generated after a data buffer transfer.

SPORT0 936 has a multichannel interface to selectively receive and transmit a 24- or 32-word, time-division multiplexed, serial bitstream. SPORT1 938 can be configured to have two external interrupts (\overline{IRQ0} and \overline{IRQ1}) and the Flag In and Flag Out signals. The internally generated serial clock may still be used in this configuration.

The interrupt controller allows the processor to respond to the eleven possible interrupts and reset with minimum overhead. The ADSP-2181 provides four dedicated external interrupt input pins, \overline{IRQ2}, \overline{IRQL0}, \overline{IRQL1} and IRQE. In addition, SPORT1 938 may be reconfigured for \overline{IRQ0}, \overline{IRQ1}, FLAG_IN and FLAG_OUT, for a total of six external interrupts. The ADSP-2181 also supports internal interrupts from the timer 934, the byte DMA port 932, the two serial ports 936, 938, software and the power-down control circuit 940. The interrupt levels are internally prioritized and individually maskable, except for power down and reset. The \overline{IRQ2}, \overline{IRQ0} and \overline{IRQ1} input pins can be programmed to be either level- or edge-sensitive. \overline{IRQL0} and \overline{IRQL1} are level sensitive and \overline{IRQE} is edge sensitive. The priorities and vector addresses of all interrupts are shown in Table I.

TABLE I
Interrupt Priority and Interrupt Vector Addresses

| Source of Interrupt | Interrupt Vector Address (Hex) |
|---|---|
| Reset (or Power-Up with PUCR = 1) | 0000 (Highest Priority) |
| Power-Down (Non-maskable) | 002C |
| \overline{IRQ2} | 0004 |
| \overline{IRQL1} | 0008 |
| \overline{IRQL0} | 000C |
| SPORT0 Transmit | 0010 |
| SPORT0 Receive | 0014 |
| \overline{IRQE} | 0018 |
| BDMA Interrupt | 001C |
| SPORT1 Transmit or \overline{IRQ1} | 0020 |
| SPORT1 Receive or \overline{IRQ0} | 0024 |
| Timer | 0028 (Lowest Priority) |

Interrupt routines can either be nested with higher priority interrupts taking precedence or processed sequentially. Interrupts can be masked or unmasked with the IMASK register. Individual interrupt requests are logically ANDed with the bits in IMASK; the highest priority unmasked interrupt is then selected. The power-down interrupt is nonmaskable. The ADSP-2181 masks all interrupts for one instruction cycle following the execution of an instruction that modifies the IMASK register. This does not affect serial port autobuffering or DMA transfers.

The interrupt control register, ICNTL, controls interrupt nesting and defines the \overline{IRQ0}, \overline{IRQ1} and \overline{IRQ2} external interrupts to be either edge- or level-sensitive. The \overline{IRQE} pin is an external edge-sensitive interrupt and can be forced and cleared. The \overline{IRQL0} and \overline{IRQL1} pins are external level-sensitive interrupts. The IFC register is a write-only register used to force and clear interrupts.

On-chip stacks preserve the processor status and are automatically maintained during interrupt handling. The stacks are twelve levels deep to allow interrupt, loop and subroutine nesting. The following instructions allow global enable or disable servicing of the interrupts (including power down), regardless of the state of IMASK. Disabling the interrupts does not affect serial port autobuffering or DMA. ENA INTS; DIS INTS;

When the processor is reset, interrupt servicing is enabled.

Low Power Operation

The ADSP-2181 has three low power modes that significantly reduce the power dissipation when the device operates under standby conditions. These modes are: (a) Power-Down; (b) Idle; and (c) Slow Idle. The CLKOUT pin may also be disabled to reduce external power dissipation.

Power Down

The ADSP-2181 processor has a low power feature that lets the processor enter a very low power dormant state through hardware or software control. The following is a brief list of power-down features. Further details regarding the power-down feature may be found in the “System Interface” chapter of the ADSP-2100 Family User's Manual (Third Edition, September 1995), which is incorporated by reference as if more fully set forth herein.
Quick recovery from power-down. The processor begins executing instructions in as few as 100 CLKIN cycles.
Support for an externally generated TTL or CMOS processor clock. The external clock can continue running during power-down without affecting the lowest power rating and 100 CLKIN cycle recovery.
Support for crystal operation includes disabling the oscillator to save power (the processor automatically waits 4096 CLKIN cycles for the crystal oscillator to start and stabilize), and letting the oscillator run to allow 100 CLKIN cycle start up.
Power-down is initiated by either the power-down pin (PWD) or the software power-down force bit.
Interrupt support allows an unlimited number of instructions to be executed before optionally powering down. The power-down interrupt also can be used as a nonmaskable, edge-sensitive interrupt.
Context clear/save control allows the processor to continue where it left off or start with a clean context when leaving the power-down state.
The RESET pin also can be used to terminate power-down.
Power-down acknowledge pin indicates when the processor has entered power-down.

Idle

When the ADSP-2181 is in the Idle Mode, the processor waits indefinitely in a low power state until an interrupt occurs. When an unmasked interrupt occurs, it is serviced; execution then continues with the instruction following the IDLE instruction.

Slow Idle

The IDLE instruction is enhanced on the ADSP-2181 to let the processor's internal clock signal be slowed, further reducing power consumption. The reduced clock frequency, a programmable fraction of the normal clock rate, is specified by a selectable divisor given in the IDLE instruction. The format of the instruction is:
IDLE (n);

where n=16, 32, 64 or 128. This instruction keeps the processor fully functional, but operating at the slower clock rate. While it is in this state, the processor's other internal clock signals, such as SCLK, CLKOUT and timer clock, are reduced by the same ratio. The default form of the instruction, when no clock divisor is given, is the standard IDLE instruction.

When the IDLE (n) instruction is used, it effectively slows down the processor's internal clock and thus its response time to incoming interrupts. The one-cycle response time of the standard idle state is increased by n, the clock divisor. When an enabled interrupt is received, the ADSP-2181 will remain in the idle state for up to a maximum of n processor cycles (n=16, 32, 64 or 128) before resuming normal operation.

When the IDLE (n) instruction is used in systems that have an externally generated serial clock (SCLK), the serial clock rate may be faster than the processor's reduced internal clock rate. Under these conditions, interrupts must not be generated at a faster rate than can be serviced, due to the additional time the processor takes to come out of the idle state (a maximum of n processor cycles).

System Interface

FIG. 10 shows a typical basic system configuration with the ADSP-2181, two serial devices, a byte-wide EPROM, and optional external program and data overlay memories. Programmable wait state generation allows the processor to connect easily to slow peripheral devices. The ADSP-2181 also provides four external interrupts and two serial ports or six external interrupts and one serial port.

Clock Signals

The ADSP-2181 can be clocked by either a crystal or a TTL compatible clock signal. The CLKIN input cannot be halted, changed during operation or operated below the specified frequency during normal operation. The only exception is while the processor is in the power down state. Further information may be found in Chapter 9 of the ADSP-2100 Family User's Manual (Third Edition, September 1995), which is incorporated by reference as if more fully set forth herein.

If an external clock is used, it should be a TTL-compatible signal running at half the instruction rate. The signal is connected to the processor's CLKIN input. When an external clock is used, the XTAL input must be left unconnected.

The ADSP-2181 may use an input clock with a frequency equal to half the instruction rate (e.g., a 20.00 MHz input clock yields a 25 ns processor cycle, which is equivalent to 40 MHz). Normally, instructions are executed in a single processor cycle. All device timing is relative to the internal instruction clock rate, which is indicated by the CLKOUT signal when enabled.

Because the ADSP-2181 includes an on-chip oscillator circuit, an external crystal may be used. The crystal may be connected across the CLKIN and XTAL pins, with two capacitors connected. Capacitor values are dependent on crystal type and should be specified by the crystal manufacturer. A parallel-resonant, fundamental frequency, microprocessor-grade crystal may be used.

A clock output (CLKOUT) signal is generated by the processor at the processor's cycle rate. This can be enabled and disabled by the CLKODIS bit in the SPORT0 Autobuffer Control Register.

Reset

The \overline{RESET} signal initiates a master reset of the ADSP-2181. The \overline{RESET} signal must be asserted during the power-up sequence to assure proper initialization. \overline{RESET} during initial power-up must be held long enough to allow the internal clock to stabilize. If \overline{RESET} is activated any time after power-up, the clock continues to run and does not require stabilization time.

The power-up sequence is defined as the total time required for the crystal oscillator circuit to stabilize after a valid VDD is applied to the processor, and for the internal phase-locked loop (PLL) to lock onto the specific crystal frequency. A minimum of 2000 CLKIN cycles ensures that the PLL has locked, but does not include the crystal oscillator start-up time. During this power-up sequence the \overline{RESET} signal should be held low. On any subsequent resets, the \overline{RESET} signal must meet the minimum pulse width specification, tRSP.

The \overline{RESET} input contains some hysteresis; however, if an RC circuit is used to generate a \overline{RESET} signal, the use of an external Schmidt trigger is recommended. The master reset sets all internal stack pointers to the empty stack condition, masks all interrupts and clears the MSTAT register. When \overline{RESET} is released, if there is no pending bus request and the chip is configured for booting (MMAP=0), the boot-loading sequence may be performed. The first instruction is fetched from on-chip program memory location 0×0000 once boot loading completes.

Memory Architecture

The ADSP-2181 provides a variety of memory and peripheral interface options. The key functional groups are program memory, data memory, byte memory and I/O.

Program memory is a 24-bit-wide space for storing both instruction opcodes and data. The ADSP-2181 has 16K words of program memory RAM on chip and the capability of accessing up to two 8K external memory overlay spaces using the external data bus. Both an instruction opcode and a data value can be read from on-chip program memory in a single cycle.

Data memory is a 16-bit-wide space used for the storage of data variables and for memory-mapped control registers. The ADSP-2181 has 16K words on data memory RAM on chip, consisting of 16,352 user-accessible locations and 32 memory mapped registers. Support also exists for up to two 8K external memory overlay spaces through the external data bus.

Byte memory provides access to an 8-bit wide memory space through the Byte DMA (BDMA) port. The byte memory interface provides access to 4 MBytes of memory by utilizing eight data lines as additional address lines. This gives the BDMA Port an effective 22-bit address range. On power-up, the DSP can automatically load bootstrap code from byte memory.

I/O space allows access to 2048 locations of 16-bit-wide data. It is intended to be used to communicate with parallel peripheral devices such as data converters and external registers or latches.

Program Memory

The ADSP-2181 contains a 16K×24 on-chip program RAM. The on-chip program memory is designed to allow up to two accesses each cycle so that all operations can complete in a single cycle. In addition, the ADSP-2181 allows the use of 8K external memory overlays. The program memory space organization is controlled by the MMAP pin and the PMOVLAY register. Normally, the ADSP-2181 is configured with MMAP=0 and program memory.

There are 16K words of memory accessible internally when the PMOVLAY register is set to 0. When PMOVLAY is set to something other than 0, external accesses occur at addresses 0×2000 through 0×3FFF. The external address is generated as shown in Table II.

TABLE II

| PMOVLAY | Memory | A13 | A12: 0 |
|---|---|---|---|
| 0 | Internal | Not | Not Applicable |
| | | Applicable | |
| 1 | External Overlay 1 | 0 | 13 LSBs of Address |
| | | | Between 0x2000 and |
| | | | 0x3FFF |
| 2 | External Overlay 2 | 1 | 13 LSBs of Address |
| | | | Between 0x2000 and |
| | | | 0x3FFF |

This organization provides for two external 8K overlay segments using only the normal 14 address bits. This allows for simple program overlays using one of the two external segments in place of the on-chip memory. Care must be taken in using this overlay space in that the processor core (i.e., the sequencer) does not take into account the PMOVLAY register value. For example, if a loop operation was occurring on one of the external overlays and the program changes to another external overlay or internal memory, an incorrect loop operation could occur. In addition, care must be taken in interrupt service routines as the overlay registers are not automatically saved and restored on the processor mode stack. For ADSP-2100 Family compatibility, MMAP=1 is allowed. In this mode, booting is disabled and overlay memory is disabled (PMOVLAY must be 0.

Data Memory

The ADSP-2181 has 16,352 16-bit words of internal data memory. In addition, the ADSP-2181 allows the use of 8K external memory overlays. There are 16,352 words of memory accessible internally when the DMOVLAY register is set to 0. When DMOVLAY is set to something other than 0, external accesses occur at addresses 0×0000 through 0×1FFF. The external address is generated as shown in Table III.

TABLE III

| DMOVLAY | Memory | A13 | A12: 0 |
|---|---|---|---|
| 0 | Internal | Not | Not Applicable |
| | | Applicable | |
| 1 | External Overlay 1 | 0 | 13 LSBs of Address |
| | | | Between 0x0000 and |
| | | | 0x1FFF |
| 2 | External Overlay 2 | 1 | 13 LSBs of Address |
| | | | Between 0x0000 and |
| | | | 0x1FFF |

This organization allows for two external 8K overlays using only the normal 14 address bits. All internal accesses complete in one cycle. Accesses to external memory are timed using the wait states specified by the DWAIT register.

I/O Space

The ADSP-2181 supports an additional external memory space called I/O space. This space is designed to support simple connections to peripherals or to bus interface ASIC data registers. I/O space supports 2048 locations. The lower eleven bits of the external address bus are used; the upper three bits are undefined. Two instructions were added to the core ADSP-2100 Family instruction set to read from and write to I/O memory space. The I/O space also has four dedicated 3-bit wait state registers, IOWAIT0-3, which specify up to seven wait states to be automatically generated for each of four regions. The wait states act on address ranges as shown in Table IV.

TABLE IV

| Address Range | Wait State Register |
|---|---|
| 0x000-0x1FF | IOWAIT0 |
| 0x200-0x3FF | IOWAIT1 |
| 0x400-0x5FF | IOWAIT2 |
| 0x600-0x7FF | IOWAIT3 |

Composite Memory Select

The ADSP-2181 has a programmable memory select signal that is useful for generating memory select signals for memories mapped to more than one space. The \overline{CMS} signal is generated to have the same timing as each of the individual memory select signals (\overline{PMS}, \overline{DMS}, \overline{BMS}, \overline{IOMS}) but can combine their functionality.

When set, each bit in the CMSSEL register, causes the \overline{CMS} signal to be asserted when the selected memory select is asserted. For example, to use a 32K word memory to act as both program and data memory, set the PMS and DMS pin bits in the CMSSEL register and use the \overline{CMS} pin to drive the chip select of the memory; use either \overline{DMS} or \overline{PMS} as the additional address bit.

The \overline{CMS} pin functions like the other memory select signals, with the same timing and bus request logic. A 1 in the enable bit causes the assertion of the \overline{CMS} signal at the same time as the selected memory select signal. All enable bits, except the \overline{BMS} bit, default to 1 at reset.

Byte Memory

The byte memory space is a bidirectional, 8-bit-wide, external memory space used to store programs and data. Byte memory is accessed using the BDMA feature. The byte memory space consists of 256 pages, each of which is 16K×8.

The byte memory space on the ADSP-2181 supports read and write operations as well as four different data formats. The byte memory uses data bits 15:8 for data. The byte memory uses data bits 23:16 and address bits 13:0 to create a 22-bit address. This allows up to a 4 meg×8 (32 megabit) ROM or RAM to be used without glue logic. All byte memory accesses are timed by the BMWAIT register.

Byte Memory DMA

The byte memory DMA controller allows loading and storing of program instructions and data using the byte memory space. The BDMA circuit is able to access the byte memory space while the processor is operating normally, and steals only one DSP cycle per 8-, 16- or 24-bit word transferred.

The BDMA circuit supports four different data formats which are selected by the BTYPE register field. The appropriate number of 8-bit accesses are done from the byte memory space to build the word size selected. Table V shows the data formats supported by the BDMA circuit.

TABLE V

| BTYPE | Internal Memory Space | Word Size | Alignment |
|---|---|---|---|
| 00 | Program Memory | 24 | Full Word |
| 01 | Data Memory | 16 | Full Word |
| 10 | Data Memory | 8 | MSBs |
| 11 | Data Memory | 8 | LSBs |

Unused bits in the 8-bit data memory formats are filled with 0s. The BIAD register field is used to specify the starting address for the on-chip memory involved with the transfer. The 14-bit BEAD register specifies the starting address for the external byte memory space. The 8-bit BMPAGE register specifies the starting page for the external byte memory space. The BDIR register field selects the direction of the transfer. Finally the 14-bit BWCOUNT register specifies the number of DSP words to transfer and initiates the BDMA circuit transfers.

BDMA accesses can cross page boundaries during sequential addressing. A BDMA interrupt is generated on the completion of the number of transfers specified by the BWCOUNT register. The BWCOUNT register is updated after each transfer so it can be used to check the status of the transfers. When it reaches zero, the transfers have finished and a BDMA interrupt is generated. The BMPAGE and BEAD registers must not be accessed by the DSP during BDMA operations.

The source or destination of a BDMA transfer will always be on-chip program or data memory, regardless of the values of MMAP, PMOVLAY or DMOVLAY.

When the BWCOUNT register is written with a nonzero value, the BDMA circuit starts executing byte memory accesses with wait states set by BMWAIT. These accesses continue until the count reaches zero. When enough accesses have occurred to create a destination word, it is transferred to or from on-chip memory. The transfer takes one DSP cycle. DSP accesses to external memory have priority over BDMA byte memory accesses.

The BDMA Context Reset bit (BCR) controls whether the processor is held off while the BDMA accesses are occurring. Setting the BCR bit to 0 allows the processor to continue operations. Setting the BCR bit to 1 causes the processor to stop execution while the BDMA accesses are occurring, to clear the context of the processor and start execution at address 0 when the BDMA accesses have completed.

Internal Memory DMA Port (IDMA Port)

The IDMA Port provides an efficient means of communication between a host system and the ADSP-2181. The port is used to access the on-chip program memory and data memory of the DSP with only one DSP cycle per word overhead. The IDMA port cannot, however, be used to write to the DSP's memory mapped control registers.

The IDMA port has a 16-bit multiplexed address and data bus and supports 24-bit program memory. The IDMA port is completely asynchronous and can be written to while the ADSP-2181 is operating at full speed.

The DSP memory address is latched and then automatically incremented after each IDMA transaction. An external device can therefore access a block of sequentially addressed memory by specifying only the starting address of the block. This increases throughput as the address does not have to be sent for each memory access.

IDMA Port access occurs in two phases. The first is the IDMA Address Latch cycle. When the acknowledge is asserted, a 14-bit address and 1-bit destination type can be driven onto the bus by an external device. The address specifies an on-chip memory location; the destination type specifies whether it is a DM or PM access. The falling edge of the address latch signal latches this value into the IDMAA register.

Once the address is stored, data can either be read from or written to the ADSP-2181's on-chip memory. Asserting the select line (\overline{IS}) and the appropriate read or write line (\overline{IRD} and \overline{IWR} respectively) signals the ADSP-2181 that a particular transaction is required. In either case, there is a one-processor cycle delay for synchronization. The memory access consumes one additional processor cycle.

Once an access has occurred, the latched address is automatically incremented and another access can occur.

Through the IDMAA register, the DSP can also specify the starting address and data format for DMA operation.

Bootstrap Loading (Booting)

The ADSP-2181 has two mechanisms to allow automatic loading of the on-chip program memory after reset. The method for booting after reset is controlled by the MMAP and BMODE pins as shown in Table VI.

TABLE VI
Boot Summary Table

| MMAP | BMODE | Booting Method |
|---|---|---|
| 0 | 0 | BDMA feature is used in default mode to load the |
| | | first 32 program memory words from the |
| | | byte memory space. Program execution is |
| | | held off until all 32 words have been loaded. |
| 0 | 1 | IDMA feature is used to load any internal memory |
| | | as desired. Program execution is held off until |
| | | internal program memory location 0 is written |
| | | to. |
| 1 | X | Bootstrap features disabled. Program execution |
| | | immediately starts from location 0. |

BDMA Booting

When the BMODE and MMAP pins specify BDMA booting (MMAP=0, BMODE=0), the ADSP-2181 initiates a BDMA boot sequence when reset is released. The BDMA interface is set up during reset to the following defaults when BDMA booting is specified: the BDIR, BMPAGE, BIAD and BEAD registers are set to 0, the BTYPE register is set to 0 to specify program memory 24 bit words, and the BWCOUNT register is set to 32. This causes 32 words of on-chip program memory to be loaded from byte memory. These 32 words are used to set up the BDMA to load in the remaining program code. The BCR bit is also set to 1, which causes program execution to be held off until all 32 words are loaded into on-chip program memory. Execution then begins at address 0.

The ADSP-2100 Family Development Software (i.e., Revision 5.02 and later) fully supports the BDMA booting feature and can generate byte memory space compatible boot code.

The IDLE instruction can also be used to allow the processor to hold off execution while booting continues through the BDMA interface.

IDMA Booting

The ADSP-2181 can also boot programs through its Internal DMA port. If BMODE=1 and MMAP=0, the ADSP-2181 boots from the IDMA port. IDMA feature can load as much on-chip memory as desired. Program execution is held off until on-chip program memory location 0 is written to.

The ADSP-2100 Family Development Software (Revision 5.02 and later) can generate IDMA compatible boot code.

Bus Request and Bus Grant

The ADSP-2181 can relinquish control of the data and address buses to an external device. When the external device requires access to memory, it asserts the bus request (\overline{BR}) signal. If the ADSP-2181 is not performing an external memory access, then it responds to the active \overline{BR} input in the following processor cycle by:
three-stating the data and address buses and the \overline{PMS}, \overline{DMS}, \overline{BMS}, \overline{CMS}, \overline{IOMS}, \overline{RD}, \overline{WR} output drivers,
asserting the bus grant (\overline{BG}) signal, and
halting program execution.

If Go Mode is enabled, the ADSP-2181 will not halt program execution until it encounters an instruction that requires an external memory access.

If the ADSP-2181 is performing an external memory access when the external device asserts the \overline{BR} signal, then it will not three-state the memory interfaces or assert the \overline{BG} signal until the processor cycle after the access completes. The instruction does not need to be completed when the bus is granted. If a single instruction requires two external memory accesses, the bus will be granted between the two accesses.

When the \overline{BR} signal is released, the processor releases the \overline{BG} signal, reenables the output drivers and continues program execution from the point where it stopped.

The bus request feature operates at all times, including when the processor is booting and when \overline{RESET} is active.

The BGH pin is asserted when the ADSP-2181 is ready to execute an instruction, but is stopped because the external bus is already granted to another device. The other device can release the bus by de-asserting bus request. Once the bus is released, the ADSP-2181 de-asserts \overline{BG} and \overline{BGH} and executes the external memory access.

The ADSP-2181 has eight general purpose programmable input output flag pins. They are controlled by two memory mapped registers. The PFTYPE register determines the direction, 1=output and 0=input. The PFDATA register is used to read and write the values on the pins. Data being read from a pin configured as an input is synchronized to the ADSP-2181's clock. Bits that are programmed as outputs will read the value being output. The PF pins default to input during reset.

In addition to the programmable flags, the ADSP-2181 has five fixed-mode flags, FLAG_IN, FLAG_OUT, FL0, FL1 and FL2. FL0-FL2 are dedicated output flags. FLAG_IN and FLAG_OUT are available as an alternate configuration of SPORT1.

Instruction Set Description

The ADSP-2181 assembly language instruction set has an algebraic syntax that was designed for ease of coding and readability. The assembly language, which takes full advantage of the processor's unique architecture, offers the following benefits:
The algebraic syntax eliminates the need to remember cryptic assembler mnemonics. For example, a typical arithmetic add instruction, such as AR=AX0+AY0, resembles a simple equation.
Every instruction assembles into a single, 24-bit word that can execute in a single instruction cycle.
The syntax is a superset ADSP-2100 Family assembly language and is completely source and object code compatible with other family members. Programs may need to be relocated to utilize on-chip memory and conform to the ADSP-2182's interrupt vector and reset vector map.
Sixteen condition codes are available. For conditional jump, call, return or arithmetic instructions, the condition can be checked and the operation executed in the same instruction cycle.
Multifunction instructions allow parallel execution of an arithmetic instruction with up to two fetches or one write to processor memory space during a single instruction cycle.

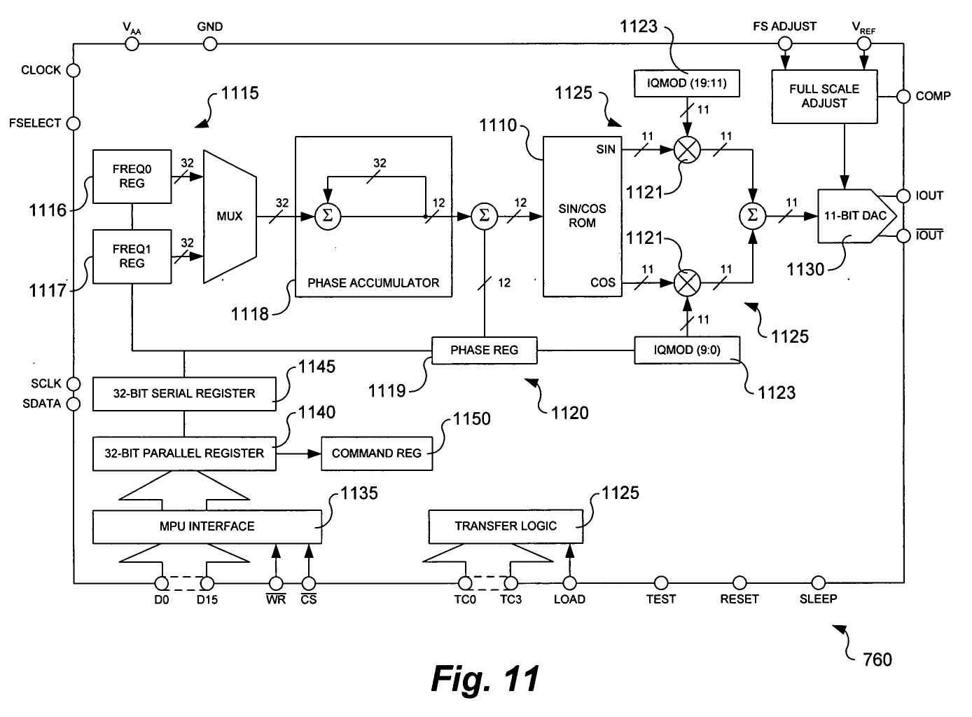

As depicted in the functional block diagram of FIG. 11, DDS 760 generally comprises a numerically controlled oscillator (NCO) 1115, SINE/COSINE look-up tables 1110, frequency 1115, phase 1120, and IQ 1125 modulators, and a digital-to-analog converter (DAC) 1130 on a single integrated circuit chip. The chip includes one reference clock, two low precision resistors and six decoupling capacitors to provide digitally created sine waves up to 25 MHz. In addition to the generation of this RF signal, the chip is fully capable of a broad range of simple and complex modulation schemes. These modulation schemes are fully implemented in the digital domain allowing accurate and simple realization of complex modulation algorithms using DSP techniques.

Theory of Operation

Sine waves are typically thought of in terms of their amplitude form:
a(t)=sin (ωt) or a(t)=cos (ωt).

However, these are nonlinear and not easy to generate except through piece wise construction. On the other hand, the angular information is linear in nature. That is, the phase angle rotates though a fixed angle for each unit of time. The angular rate depends on the frequency of the signal by the traditional rate of: ω=2πf.

Knowing that the phase of a sine wave is linear and given a reference interval (i.e., clock period), the phase rotation for that period can be determined.
ΔPhase=ωdt

Solving for ω:

$$ω = \frac{Δ Phase}{dt} = 2 π f$$

Solving for f and substituting the reference clock frequency for the reference period:

$$( \frac{1}{{f}_{CLOCK}} ) = dt \text{:}$$

$$f = \frac{Δ Phase \times {f}_{CLOCK}}{2 π}$$

DDS 760 builds the output based on this simple equation. A simple DDS chip will implement this equation with three major subcircuits. The AD7008 includes an extra section for I and Q modulation.

Numerically Controlled Oscillator+Phase Modulator

NCO 1115 generally comprises two frequency select registers 1116, 1117, a phase accumulator 1118, and a phase offset register 1119. The main component of NCO 1115 is the 32-bit phase accumulator 1118, which assembles the phase component of the output signal. Continuous time signals have a phase range 0 to 2π. Outside this range of numbers, the sinusoidal functions repeat themselves in a periodic manner. The digital implementation is no different. Phase accumulator 1118 simply scales the range of phase numbers into a multi-bit digital word. In the AD7008, phase accumulator 1118 is implemented with 32 bits. Therefore in DDS 760, 2π=2³². Likewise, the ΔPhase term is scaled into this range of numbers:
0≦ΔPhase≦2³²−1

Making these substitutions into the equation above:

$$f = \frac{Δ Phase \times {f}_{CLOCK}}{{2}^{32}} , where 0 \leq Δ Phase < {2}^{32}$$

With a clock signal of 50 MHz and a phase word of 051EB852 hex:

$$f = \frac{51 EB 852 \times 50 MHz}{{2}^{32}} = 1.000000000931 MHz$$

The input to phase accumulator 1118 (i.e., the phase step) can be selected either from FREQ0 Register 1116 or FREQ1 Register 1117, and this is controlled by the FSELECT pin. in the AD7008, phase accumulator 1118 inherently generates a continuous 32-bit phase signal, thus avoiding any output discontinuity when switching between frequencies. This facilitates complex frequency modulation schemes, such as GMSK.

Following NCO 1115, a phase offset can be added to perform phase modulation using the 12-bit phase register 1119. The contents of this register 1119 are added to the most significant bits of NCO 1115.

Sine and Cosine Look-Up Tables

To make the output useful, the signal must be converted from phase information into a sinusoidal value. Since phase information maps directly into amplitude, a ROM look up table (LUT) converts the phase information into amplitude. To do this the digital phase information is used to address a Sine/Cosine ROM LUT 1110. Only the most significant 12 bits are used for this purpose. The remaining 20 bits provide frequency resolution and minimize the effects of quantization of the phase to amplitude conversion.

In Phase and Quadrature Modulators

Two 10-bit amplitude multipliers 1121 are provided allowing the easy implementation of either Quadrature Amplitude Modulation (QAM) or Amplitude Modulation (AM). The 20-bit IQMOD Register 1123 is used to control the amplitude of the I (cos) and Q (sin) signals. IQMOD [9:0] controls the I amplitude and IQMOD [19:10] controls the Q amplitude.

The user should ensure that when summing the I and Q signals the sum should not exceed the value that a 10-bit accumulator can hold. DDS 760 does not clip the digital output; the output will roll over instead of clip. When amplitude modulation is not required, the IQ multipliers 1121 can be bypassed (CR=2). The sine output is directly sent to the 10-bit DAC 1030.

Digital-to-Analog Converter

DDS 760 ALSO includes a high impedance current source 10-bit DAC 1130, which is capable of driving a wide range of loads at different speeds. Full-scale output current can be adjusted, for optimum power and external load requirements, through the use of a single external resistor (RSET). DAC 1130 can be configured for single or differential-ended operation. \overline{IOUT} may be tied directly to AGND for single-ended operation or through a load resistor to develop an output voltage. The load resistor can be any value required as long as the full-scale voltage developed across it does not exceed 1 volt. Since full-scale current is controlled by RSET, adjustments to RSET can balance changes made to the load resistor.

DSP and MPU Interfacing

DDS 760 also contains a 32-bit parallel assembly register 1140 and a 32-bit serial assembly register 1145. Each of the modulation registers 1116, 1117, 1119, 1125 can be loaded from either assembly register 1140, 1145 under control of the LOAD pin and the Transfer-Control (TC) pins. The command register 1150 can be loaded only from the parallel assembly register 1140. In practical use, both serial and parallel interfaces can be used simultaneously if the application requires. TC3-TC0 should be stable before the LOAD signal rises and should not change until after LOAD falls.

The DSP/MPU interface 1135 asserts both \overline{WR} and \overline{CS} to load the parallel assembly register 1140. At the end of each write, the parallel assembly register 1140 is shifted left by 8 or 16 bits (i.e., depending on CR0), and the new data is loaded into the low bits. Hence, two 16-bit writes or four 8-bit writes may be used to load the parallel assembly register 1140. When loading parallel data, it is only necessary to write as much data as will be used by that register. For instance, the command register 1150 requires only one write to the parallel assembly register 1140.

Serial data is input to the chip on the rising edge of SCLK, most significant bit first. The data in the assembly registers 1140, 1145 can be transferred to the modulation registers 1116, 1117, 1119, 1125 by means of the transfer control pins.

Maximum Updating of the DDS

Updating DDS 760 need not take place in a synchronous fashion. However, in asynchronous systems, most of the external clock pulses (LOAD and SCLK) must be high for greater than one system clock period. This insures that at least one CLOCK rising edge will occur successfully completing the latch function.

However, if DDS 760 is run in a synchronous mode with the controlling DSP (e.g., DSP 720) or microcontroller, it may be loaded very rapidly. Optimal speed is attained when operated in the 16-bit load mode; the following discussion will assume that mode is used. Each of the modulation registers 1116, 1117, 1119, 1125 require two 16-bit loads. This data is latched into the parallel assembly register 1140 on the falling edge of the \overline{WR} command. This strobe is not qualified by the CLOCK pulse but must be held low for a minimum of 20 ns and only need be high for 10 ns. The two 16-bit words may be loaded in succession. While the second 16-bit word is being latched into the parallel assembly register 1140, the Transfer and Control word may be presented to the TC3-TC0 pins. If the designation register is always the same, an external register can be used to store the information on the inputs of TC3-TC0. At some time after the second falling edge of \overline{WR}, the LOAD signal may go high. As long as the load signal is high 5 ns before the rising edge of the CLOCK signal, data will be transferred to the destination register.

The limiting factor of this technique is the \overline{WR} period which is 30 ns. Thus the CLOCK may run up to 33 MSPS using this technique and the effective update rate would be one half or 16.5 MHz. See e.g., FIG. 10 of the AD7008 CMOS DDS Modulator Data Sheet, (Revision B, 1995) for timing details. For the purposes of this disclosure, that entire data sheet is incorporated by reference as if more fully set forth herein.

Applications

Serial Configuration

Data may be written to DDS 760 in serial mode using the two signal lines SDATA and SCLK. Data is accumulated in the serial assembly register 1145 with the most significant bit loaded first. The data bits are loaded on the rising edge of the serial clock. Once data is loaded in the serial assembly register 1145, it must be transferred to the appropriate register on chip. This is accomplished by setting the TC bits according to Tables II and III of the AD7008 CMOS DDS Modulator Data Sheet (Revision B, 1995), which is incorporated herein by reference. If one wants to load the serial assembly register 1145 into FREQ1 register 1017, the TC bits should be 1101. When the LOAD pin is raised, data is transferred directly to the FREQ1 register 1117. When operating in serial mode, some functions must still operate in parallel mode such as loading the TC bits and updating the command register 1150, which is accessed only through the parallel assembly register 1140. For a typical serial mode configuration, see, e.g., FIG. 11 of the AD7008 CMOS DDS Modulator Data Sheet (Revision B, 1995), which is incorporated herein by reference.

Parallel Configuration

The AD7008 functions fully in the parallel mode. There are two parallel modes of operation. Both are similar but are tailored for different bus widths, 8 and 16 bits. All modes of operation can be controlled by the parallel interface. On power up and reset, the chip must be configured by instructing the command register how to operate. The command register 1150 may be used to set the device up for 8- or 16-bit mode, sleep mode, amplitude control and synchronization logic. At reset, the chip defaults to 8-bit bus, no amplitude control and logic synchronized.

Local Oscillator

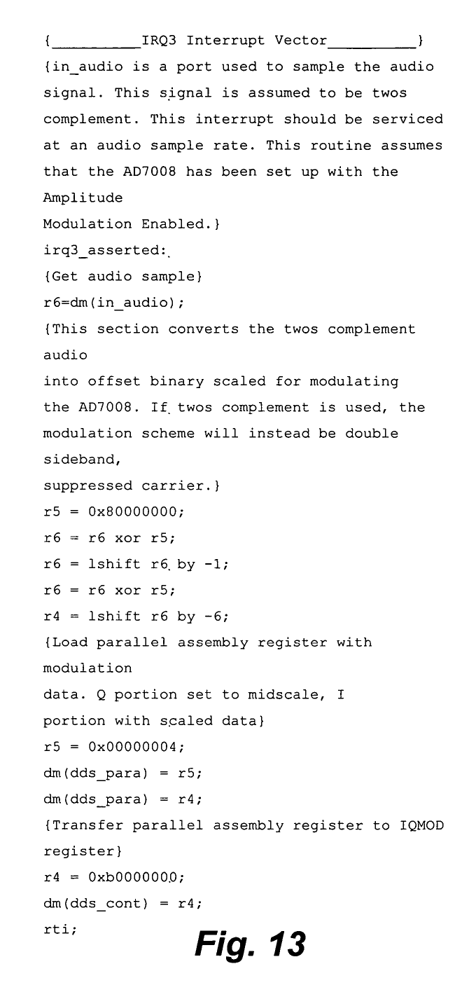

The AD7008 is well suited for applications such as local oscillators used in super-heterodyne receivers. Although the AD7008 can be used in a variety of receiver designs, one simple local oscillator application is with the AD607 Monoceiver™ (a trademark of Analog Devices, Inc.). This unique two-chip combination provides a complete receiver subsystem with digital frequency control, RSSI and demodulated outputs for AM, FM and complex I/Q (SSB or QAM). See, e.g., FIG. 13 of the AD7008 CMOS DDS Modulator Data Sheet (Revision B, 1995). For the purposes of this disclosure, that entire data sheet is incorporated by reference as if more fully set forth herein.

Direct Digital Modulator

In addition to the basic DDS function provided by the AD7008, the device also offers several modulation capabilities useful in a wide variety of application. The simplest modulation scheme is frequency shift keying or FSK. In this application, each of the two frequency registers 1116, 1117 is loaded with a different value, one representing the space frequency and the other the mark frequency. The digital data stream is fed to the FSELECT pin causing DDS 760 to modulate the carrier frequency between the two values.

As noted above, DDS 760 has three types of registers 1116, 1117, 1119, 1125 that can be used for modulation. Besides the example of frequency modulation shown above, the frequency registers 1116, 1117 can be updated dynamically as can the phase register 1119 and the IQMOD register 1123. These can be modulated at rates up to 16.5 MHz. The example shown in FIG. 12 along with code fragment depicted in FIG. 13 show how to implement DDS 760 in an amplitude modulation scheme. Other modulation schemes may be implemented, without undue experimentation, by those of ordinary skill in the art in a similar fashion.

Many applications require precise control of the output amplitude, such as in local oscillators, signal generators and modulators. There are several methods to control signal amplitude. The most direct is to program the amplitude using the IQMOD register 1123 on DDS 760. Other methods include selecting the load resistor value or changing the value of RSET. Another option is to place a voltage out DAC 1130 on the ground side of RSET. This allows easy control of the output amplitude without affecting other functions of the AD7008. Any combination of these techniques may be used as long as the full-scale voltage developed across the load does not exceed 1 volt.

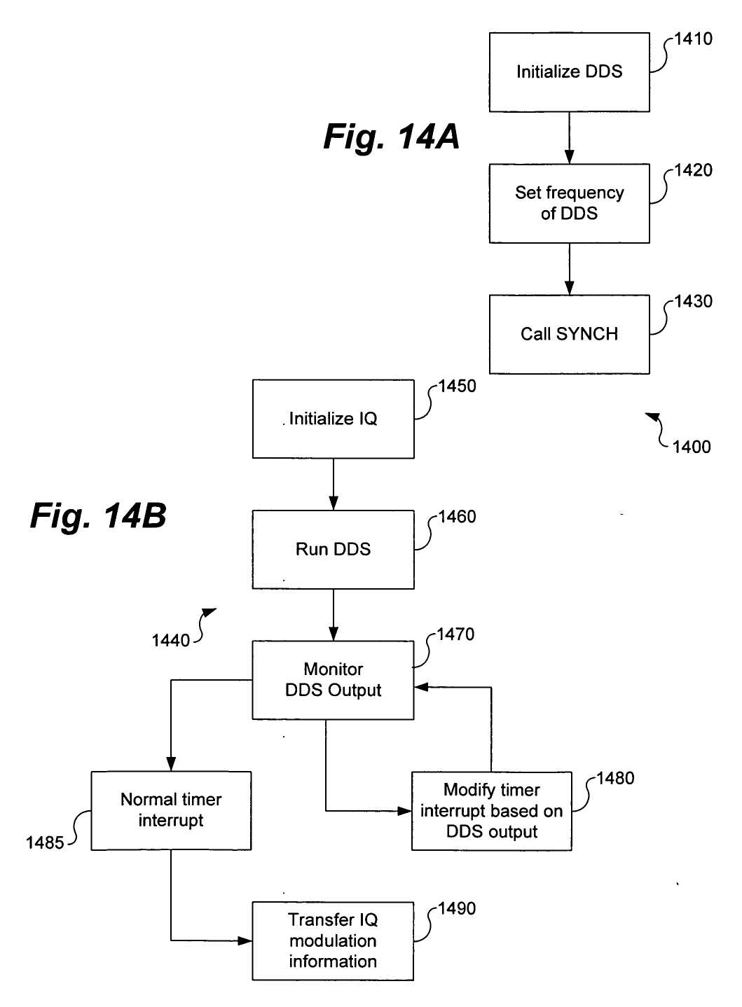

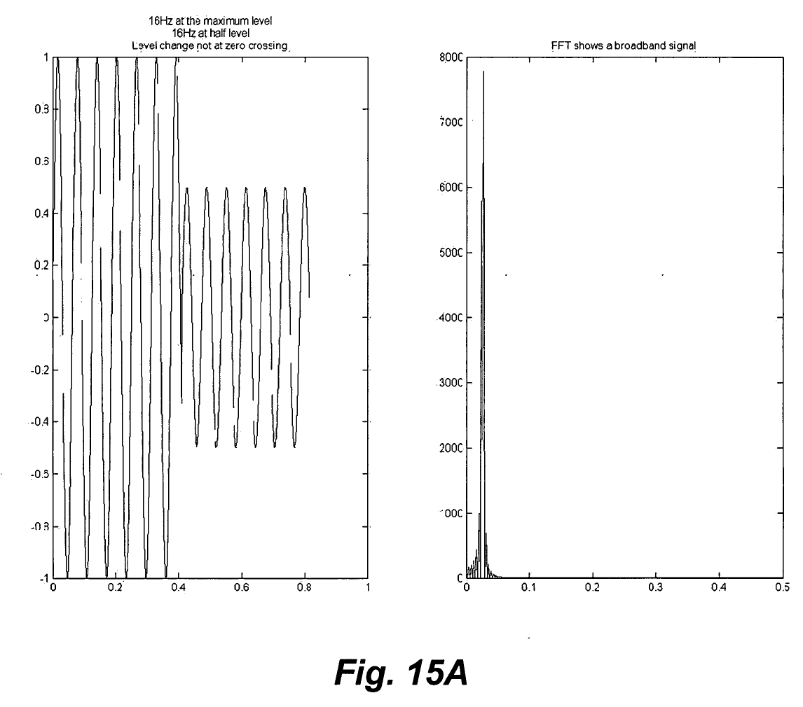

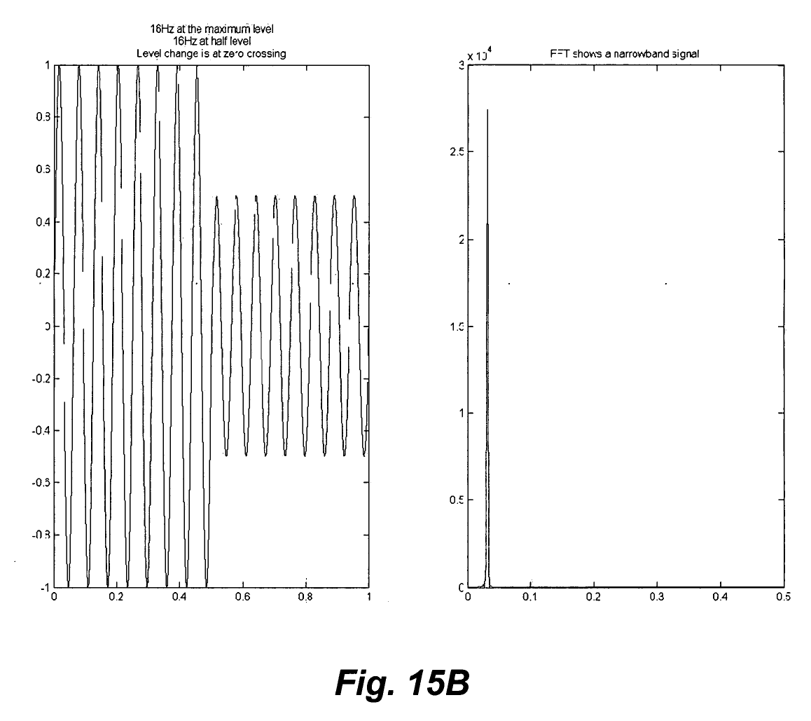

Referring now to FIGS. 14A and 14B, methods for narrow bandwidth amplitude modulation according to embodiments of the present invention will now be described. One goal of the system 700 is to transfer the modulation value from the DSP 730 to the IQMOD registers 1123 of the DDS 760 so that the DDS modulation stage receives the modulation change at the same time as the RF carrier zero crossing arrives at the modulation stage.

Since the AD7008 does not have a software command to reset the phase accumulator 1118, it may be necessary to manually adjust the timing relationship between the RF carrier and the modulation change. When the desired synchronization is approached, the sidebands amplitudes are reduced. It also may be possible to program the AD7008 to achieve the zero crossing synchronization without the need of resorting to such manual synchronization.

Details of Code

As discussed in greater detail herein above, the real time DSP code uses interrupts to trigger various functions to control the DDS 760. Programming of the DSP interrupts requires:
Manual counting of DSP and DDS machine cycles;
Disabling/enabling of interrupts within each interrupt handler; and
Programming of the DSP timer 934.

Timer Interrupt

The TCOUNT register of the DSP timer 934 is set to the number stored in the TPERIOD timer register. The value in TCOUNT is the decremented on each DSP clock cycle. When the TCOUNT reaches zero, the timer interrupt handler code is called. The timer interrupt handler code transfers the modulation information (i.e., audio) to the IQMOD register 1123 of DDS 760. At the same time TCOUNT is reloaded from the value in TPERIOD.

Preferably, DDS 760 and DSP 810 will be connected to the same clock. Since they would thus be running from the same clock, once the DSP timer 934 is synchronized with the RF carrier zero crossing, both devices will remain synchronized. One difficulty may be getting DDS 760 and DSP 810 into synchronization. When a synchronization adjustment is required, push button 830 on the DSP board 720 causes the DSP timer TCOUNT value to be modified for one timer period. At the end of this modified timer period, the timer value would be reset to the original value. The result of this adjustment is a different phase relationship between DDS 760 and DSP 810. When the code is running after synchronization, two interrupt handlers may be called often. Each handler has code to prevent the other from being called during its own operation, as noted below.

Timer

This interrupt handler is only called at precise times that result in synchronization between the RF carrier and modulation. The actual code, which transfers modulation data from the DSP to the DDS, is only a few cycles long. If the timer expires during the A/D interrupt handler, the timer interrupt handler must not be called since the timing would be wrong.

A/D Input

The A/D converter interrupt handler is called periodically when audio data is received from the AID converter 825. The A/D converter interrupt handler has a lot more code than the timer interrupt handler. The A/D converter interrupt handler can include digital filters. The A/D converter interrupt handler can be called after the timer interrupt handler finishes, if the A/D interrupt happened during the timer interrupt handler.

The first step in performing methods according to embodiments of the present invention is to set up the DSP interrupts as noted above. That is, one must ensure that the:
frequency selected for the AD7008 DDS results in an integral number of DDS phases at the DDS phase accumulator register. This will guarantee that an exact RF zero crossing exists;
timer interrupt handler transfers modulation data a precise number of DDS cycles prior to the DDS RF zero crossing;
A/D input interrupt handler processes new audio data; and
push button interrupt handler adjusts RF carrier synchronization with modulation changes.

Then, as shown in FIG. 14A, one must initialize DDS 760 at step 1410, set the frequency of DDS 760 at step 1420, and call SYNCH (i.e., synchronize DDS 760) at step 1430. In a manual mode, this may be done by observing the amplitude of sidebands at the output from DDS 760, and adjusting the synchronization of RF with modulation to substantially minimize sidebands.

In an automatic mode, methods according to embodiments of the present invention may include the steps shown in FIG. 14B. First, the IQMOD registers 1123 are initialized at step 1450, DDS 760 is run at step 1460, outputs from DDS 760 are monitored to determine the proximity of level changes to the zero crossing (e.g., with a zero crossing detector) at step 1470, a hardware interrupt is performed at step 1480 based on the outputs from DDS 760, and the IQ modulation information is transferred at step 1490 only when such level changes are substantially at the zero crossings.

The first step in this automatic mode would be to set the DDS frequency register, which starts the DDS. The frequency selected must have an exact RF zero crossing at an integral number of phases as seen by the phase accumulator. Then the DDS timer would be set. That is, the time would be preset to a value that will match repeated RF zero crossings. This may be accomplished by setting the IQMOD register to a fixed, non-zero value to get an output from the DDS. The DDS output may then be monitored to provide an interrupt input to the DSP when a zero crossing is detected. The DSP will adjust the DDS RF phase until a detected RF crossing (e.g., the external RF zero crossing detector will repeatedly match the DSP timer interrupt timing).

To accomplish the RF phase adjustment, the DSP timer interrupt handler will modify the frequency of the DDS for one DSP timer interrupt period. After one phase adjustment timer period, the DDS frequency will be reset to the normal DDS frequency. There will be a known fixed delay between: (a) the time that the DDS internal RF zero crossing arrives at the DDS modulator stage; and (b) the time that the external RF zero crossing detector detects an RF zero crossing.

After the internal DDS RF zero crossing has been calculated, the external zero crossing detector is no longer needed as long as the DDS continues running at the same frequency. The DSP timer now corresponds to the DDS internal RF zero crossing.

Embodiments of the present invention may include apparatuses for performing the operations disclosed herein. An apparatus may be specially constructed for the desired purposes, or it may comprise a general-purpose device selectively activated or reconfigured by a program stored in the device.

Embodiments of the invention may be implemented in one or a combination of hardware, firmware, and software. Embodiments of the invention may also be implemented as instructions stored on a machine-readable medium, which may be read and executed by a computing platform to perform the operations described herein. A machine-readable medium may include any mechanism for storing or transmitting information in a form readable by a machine (e.g., a computer). For example, a machine-readable medium may include read only memory (ROM); random access memory (RAM); magnetic disk storage media; optical storage media; flash memory devices; electrical, optical, acoustical or other form of propagated signals (e.g., carrier waves, infrared signals, digital signals, etc.), and others.

Of course, only analog signaling is possible in optical fiber, since only light waves may be transmitted. With appropriate modulation, either digital or analog data may be carried.

The invention has been described in detail with respect to various embodiments, and it will now be apparent from the foregoing to those skilled in the art that changes and modifications may be made without departing from the invention in its broader aspects. For example, it should be readily understood that ideally, the amplitude changes will take place exactly at a zero crossing. It is, nevertheless, desirable to apply the modulating signal as close as possible to the zero crossing. Since some infinitesimal time will always, elapse, the change will be centered around the zero crossing. Thus, the staircase step will begin slightly before the zero crossing and end slightly after the zero crossing. The invention, therefore, as defined in the appended claims, is intended to cover all such changes and modifications as fall within the true spirit of the invention.

What is claimed is:

1. A method of narrow band amplitude modulation, comprising:
providing a first signal comprising a radio frequency (RF) sine wave;
providing a second signal comprising a staircase waveform; and
multiplying said first and second signals to produce a narrow band amplitude modulated signal.

2. The method according to claim 1, wherein said step of providing said second signal further comprises:
providing a time-varying signal; and
sampling and holding said time-varying signal to produce said staircase waveform.

3. The method according to claim 1, wherein:
said first signal comprises a carrier signal which, in its unmodulated state, further comprises a plurality of zero crossings;
said staircase waveform comprising said second signal includes a plurality of changes in amplitude; and
said second signal is applied to said first signal such that each of said plurality of amplitude changes occur only at a corresponding one of said plurality of zero crossings.

4. A system for narrow band amplitude modulation, comprising:
an analog to digital converter adapted to receive an analog signal and convert said analog signal into a digital signal;
a digital signal processor, coupled to said analog to digital converter and adapted to receive said digital signal and thereafter output a pair of processed signals;
a direct digital synthesizer adapted to receive a first of said pair of processed signals and output therefrom a modulated signal;
a mixer, coupled both to said digital signal processor and adapted to receive therefrom a second of said pair of processed signals, and to said direct digital synthesizer and adapted to receive therefrom said modulated signal, wherein said mixer includes means for outputting therefrom a mixed signal only when a level change in said second of said pair of processed signals is substantially proximate to a zero crossing of said modulated signal; and
a digital to analog converter coupled to said mixer to convert said signal output from said mixer into a modulated analog signal.

5. The system according to claim 4, further comprising a clock coupled to said digital signal processor and to said direct digital synthesizer such that said digital signal processor and to said direct digital synthesizer may be synchronized.

6. The system according to claim 5, further comprising a timer within said digital signal processor, said timer including a pair of registers which are coupled together.

7. The system according to claim 6, wherein a first of said pair of registers is adapted to be initially set by a number contained in a second of said pair of registers, and said first register is thereafter decremented on each of a plurality of clock cycles of said clock.

8. The system according to claim 7, further comprising a computer-readable medium containing software code implementing the steps of:
determining when a count in said first register equals zero;
calling an interrupt handler;
transferring modulation information from the digital signal processor to the direct digital synthesizer; and
reloading said first register with said number from said second register.

9. The system according to claim 8, wherein said interrupt handler comprises a timer interrupt handler.

10. The system according to claim 8, further comprising a pair of interrupt handlers.

11. The system according to claim 10, wherein said pair of interrupt handlers comprises a timer interrupt handler and an analog to digital converter interrupt handler.

12. The system according to claim 11, wherein said software code further comprises the step of preventing said timer interrupt handler from being called during the handling of said analog to digital converter interrupt handler.

13. The system according to claim 12, wherein said software code further comprises the steps of:
preventing said analog to digital converter interrupt handler from being called to the handling of said timer interrupt handler; and
calling said analog to digital converter interrupt handler upon completion of said timer interrupt handler.

14. The system according to claim 11, wherein said analog to digital converter interrupt handler further comprises a digital filter.

15. A transmission system, comprising:
an analog to digital converter adapted to receive an analog signal and convert said analog signal into a digital signal;
a digital signal processor, coupled to said analog to digital converter and adapted to receive said digital signal and thereafter output a pair of processed signals;
a direct digital synthesizer adapted to receive a first of said pair of processed signals and output therefrom a modulated signal;
a mixer, coupled both to said digital signal processor and adapted to receive therefrom a second of said pair of processed signals, and to said direct digital synthesizer and adapted to receive therefrom said modulated signal, wherein said mixer includes means for outputting therefrom a mixed signal only when a level change in said second of said pair of processed signals is substantially proximate to a zero crossing of said modulated signal; and
a digital to analog converter coupled to said mixer to convert said signal output from said mixer into a modulated analog signal for transmission through a transmission medium.

16. The transmission system according to claim 15, wherein said transmission medium comprises a medium selected from the group consisting of a wireline medium, a wireless medium, and an optical medium.

17. The transmission system according to claim 15, wherein said transmission medium comprises a combination of two or more of a wireline medium, a wireless medium, and an optical medium.

18. The transmission system according to claim 15, wherein said modulated analog signal comprises a modulated radiofrequency (RF) signal.

19. The transmission system according to claim 15, wherein said modulated analog signal frequency comprises a signal in the range of about 3 kilohertz to about 300,000 megahertz.
